(19) United States
(12) Patent Application Publication
(10) Pub. No.: US 2008/0079141 A1
(43) Pub. Date: Apr. 3, 2008

(54) MICRO ELECTRO-MECHANICAL SYSTEM MODULE PACKAGE CAPABLE OF MINIMIZING INTERFERENCE OF NOISES

(75) Inventors: Jiung-Yue Tien, Taichung County (TW); Ming-Te Tu, Taichung County (TW); Chin-Ching Huang, Taichung County (TW)

Correspondence Address: BROWDY AND NEIMARK, P.L.L.C.;624 NINTH STREET, NW, SUITE 300, WASHINGTON, DC, 20001-5303, US

(73) Assignee: Lingsen Precision Industries, Ltd., Taichung (TW)

(21) Appl. No.: 11/771,019

(22) Filed: Jun. 29, 2007

(30) Foreign Application Priority Data
Oct. 3, 2006 (TW) 95217673

(51) Int. Cl. H01L 23/08

(52) U.S. Cl. 257/704; 257/E23.192

(57) ABSTRACT

A MEMS module package includes a housing with an accommodation chamber and an opening in communication with the accommodation chamber. The housing has a substrate and an electrically insulative cap capped on the substrate and defining with the substrate the accommodation chamber therebetween. A micro electro-mechanical chip is installed on the substrate and located inside the accommodation chamber. The micro electro-mechanical chip has an action zone corresponding to the opening of the housing. A first conducting layer and a second conducting layer are respectively disposed on an inner surface and an outer surface of the electrically insulative cap.

### BACKGROUND OF THE INVENTION

1. Field of the Invention

The present invention relates generally to a package for a micro electro-mechanical system module (hereinafter referred to as “MEMS module”) and more particularly, to a cap package for a MEMS module, which can minimize the interference of noises, such as electromagnetic interference and radio frequency noise.

2. Description of the Related Art

Micro Electro-Mechanical System (MEMS) is the integration of mechanical elements, sensors, actuators, and electronics on a common silicon substrate through microfabrication technology. To improve the performance of a MEMS module, mechanical support strength, environmental factors, such as interference of noises, electrical connection condition, heat resistivity and many other factors must be taken into account during packaging

Conventionally, a MEMS module is packaged with a metal cap by means of cap package process. This cap package can only isolate electromagnetic interference (hereinafter referred to as “EMI”). It cannot protect against the interference of AC noises or radio frequence noises, which may affect the working performance of the MEMS module. In other words, the conventional cap package for a MEMS module has a drawback of low shielding effectiveness. Therefore, it is desirable to provide an improved cap package for a MEMS module that can eliminate the aforesaid drawbacks.

### SUMMARY OF THE INVENTION

The present invention has been accomplished under the circumstances in view. It is therefore one objective of the present invention to provide a MEMS module package, which can minimize the interference of noises.

To achieve this objective of the present invention, the MEMS module package comprises a housing with an accommodation chamber and an opening in communication with the accommodation chamber, a micro electro-mechanical chip, a first conducting layer and a second conducting layer. The housing has a substrate and an electrically insulative cap capped on the substrate and defining with the substrate the accommodation chamber therebetween. The micro electro-mechanical chip is installed on the substrate and located inside the accommodation chamber. The micro electro-mechanical chip has an action zone corresponding to the opening of the housing. A first conducting layer and a second conducting layer are respectively disposed on an inner surface and an outer surface of the electrically insulative cap.

In a preferred embodiment of the present invention, the first conducting layer can be made of a metal material and the second conducting layer can be made of a non-metal material, e.g. carbon, having a resistance ranging from 10⁴Ω to 10⁹Ω. The substrate of the housing can be provided with a first conducting portion electrically connected with the first conducting layer and a DC power supply, and a second conducting portion electrically connected to the second conducting layer and grounded. In addition, the opening of the housing can be formed at the substrate. In another preferred embodiment, the opening of the housing is formed at the electrically insulative cap.

By means the above-mentioned structure, the MEMS module package of the present invention can effectively minimize the interference of noises, e.g. the electromagnetic interference and radio frequency noise especially.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic drawing showing a sectional view of a MEMS module package in accordance with a first preferred embodiment of the present invention;

FIG. 2 is a schematic top view of the substrate of the MEMS module package according to the first preferred embodiment of the present invention;

FIG. 3 is a schematic drawing of the first preferred embodiment of the present invention, showing the relative positioning between the substrate and the first and second conducting layers, and

FIG. 4 is a schematic drawing showing a sectional view of a MEMS module package in accordance with a second preferred embodiment of the present invention.

### DETAILED DESCRIPTION OF THE INVENTION

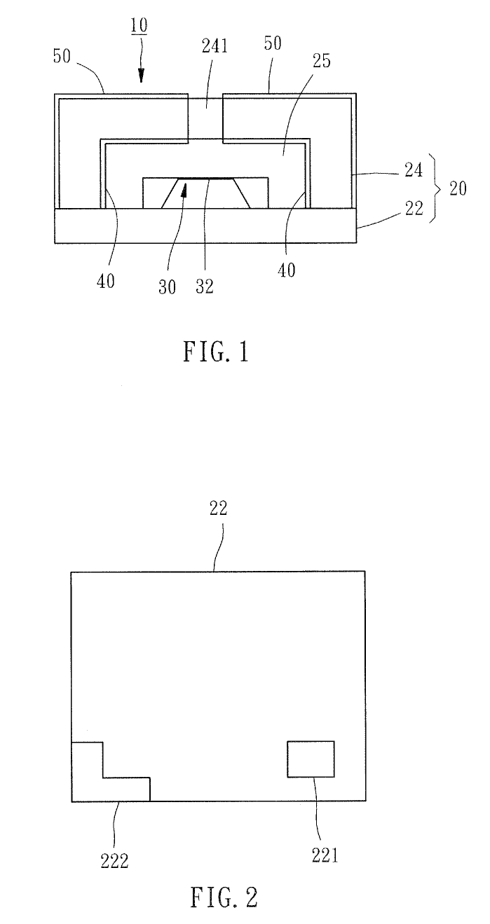

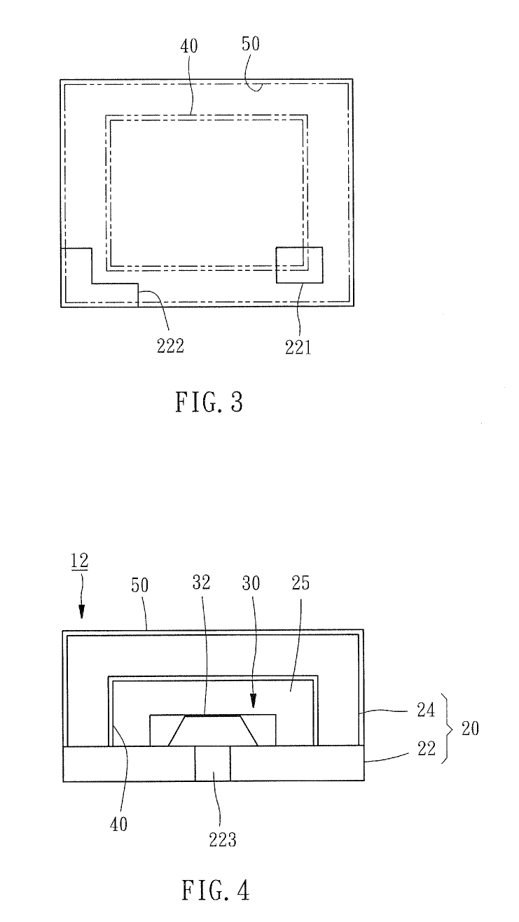

As shown in FIGS. 1-3, a MEMS module package 10 in accordance with a first preferred embodiment of the present invention comprises a housing 20, a micro electro-mechanical chip 30, a first conducting layer 40 and a second conducting layer 50.

The housing 20 includes a substrate 22 and an electrically insulative cap 24. The substrate 22 has a first conducting portion 221 and a second conducting portion 222. The first conducting portion 221 is electrically connected to a DC power supply (not shown). The second conducting portion 222 is grounded. The cap 24 is injection-molded from plastics, having an opening 241. The cap 24 is capped on the substrate 22, defining with the substrate 22 an accommodation chamber 25 therebetween.

The micro electro-mechanical chip 30 is installed on the substrate 22 and located inside the accommodation chamber 25. The micro electro-mechanical chip 30 has an action zone 32 corresponding to the opening 241. The action zone 32 is a thin film at the center of the micro electro-mechanical chip 30.

The first conducting layer 40 is prepared from a metal material and applied to the inner surface of the cap 24 by film coating, and electrically connected to the first conducting portion 221.

The second conducting layer 50 is prepared from a non-metal material, for example carbon, having a resistance ranging from about 10⁴Ω to 10⁹Ω and applied to the outer surface of the cap 24 by film coating. The second conducting layer 50 is electrically connected to the second conducting portion 222.

The first conducting layer 40 and the second conducting layer 50 of the MEMS module package 10 constitute a decoupling capacitor to isolate electromagnetic noises and radio frequency noises, preventing coupling interference therebetween. Therefore, the MEMS module package of the present invention effectively avoids the interference of electromagnetic noises and radio frequency noises, eliminating the drawbacks of the prior art cap package using a metal cap.

FIG. 4 illustrates a MEMS module package 12 in accordance with a second preferred embodiment of the present invention. Similar to the aforesaid first embodiment, the MEMS module package 12 comprises a housing 20, a micro electro-mechanical chip 30, a first conducting layer 40 and a second conducting layer 50. According to this embodiment, the substrate 22 has an opening 223 corresponding to the action zone 32, and the cap 24 fully shields the micro electro-mechanical chip 30.

Except the opening 223 at the substrate 22 to substitute for the opening 241 at the cap 24 in the aforesaid first embodiment, the MEMS module package 12 of the second embodiment of the present invention has the same features of the aforesaid first embodiment. Therefore, this second embodiment achieves the same effect as the aforesaid first embodiment.

As indicated above, the MEMS module package of the present invention uses decoupling capacitor technology to overcome the drawbacks of the prior art cap package using a metal cap, that is, the MEMS module package of the present invention can minimize the interference of noises, for example the electromagnetic interference and the radio frequency noise especially.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A MEMS module package comprising:
a housing having a substrate and an electrically insulative cap capped on the substrate and defining with the substrate an accommodation chamber therebetween, the housing having an opening in communication with the accommodation chamber;
a micro electro-mechanical chip installed on the substrate and located inside the accommodation chamber, the micro electro-mechanical chip having an action zone corresponding to the opening of the housing;
a first conducting layer disposed on an inner surface of the electrically insulative cap; and
a second conducting layer disposed on an outer surface of the electrically insulative cap.

2. The MEMS module package as claimed in claim 1, wherein the first conducting layer is made of a metal material.

3. The MEMS module package as claimed in claim 1, wherein the second conducting layer is made of a non-metal material.

4. The MEMS module package as claimed in claim 3, wherein the non-metal material is carbon.

5. The MEMS module package as claimed in claim 3, wherein the non-metal material has a resistance ranging from 10⁴Ω to 10⁹Ω.

6. The MEMS module package as claimed in claim 1, wherein the substrate comprises a first conducting portion electrically connected to the first conducting layer, and a second conducting portion electrically connected to the second conducting layer; the first conducting layer and the second conducting layer have a voltage difference.

7. The MEMS module package as claimed in claim 6, wherein the first conducting portion is electrically connected to a DC power supply; the second conducting portion is grounded.

8. The MEMS module package as claimed in claim 1, wherein the opening of the housing is formed at the substrate.

9. The MEMS module package as claimed in claim 1, wherein the opening of the housing is formed at the electrically insulative cap.

10. The MEMS module package as claimed in claim 1, wherein the electrically insulative cap is injection-molded from plastics.
